(19) United States
(12) Patent Application Publication
(10) Pub. No.: US 2025/0054767 A1
(43) Pub. Date: Feb. 13, 2025

(54) SELECTIVE METAL CAPPING PROCESSES FOR A JUNCTION SILICIDE

(71) Applicant: Applied Materials, Inc., Santa Clara, CA (US)

(72) Inventors: Qihao ZHU, Sunnyvale, CA (US); Shumao ZHANG, San Jose, CA (US); Weifeng YE, San Jose, CA (US); Yiyang WAN, Sunnyvale, CA (US); Gary HOW, Santa Clara, CA (US); Jianqiu GUO, San Jose, CA (US); Dong WANG, Zhuhai (CN); Shihchung CHEN, Cupertino, CA (US); Liqi WU, San Jose, CA (US); Jiang LU, Milpitas, CA (US)

(21) Appl. No.: 18/646,055

(22) Filed: Apr. 25, 2024

Related U.S. Application Data
(63) Continuation-in-part of application No. 18/400,819, filed on Dec. 29, 2023.
(60) Provisional application No. 63/532,022, filed on Aug. 10, 2023.

(51) Int. Cl. H01L 21/285; C23C 16/02; C23C 16/04; C23C 16/14; C23C 16/42; C23C 16/455; C23C 16/50; C23C 16/52; H01J 37/32; H01L 21/02; H01L 21/768

(52) U.S. Cl. CPC H01L 21/28518; C23C 16/0227; C23C 16/04; C23C 16/14; C23C 16/42; C23C 16/45525; C23C 16/50; C23C 16/52; H01J 37/32449; H01L 21/02068; H01L 21/76879; H01J 2237/332; H01J 2237/335

(57) ABSTRACT

Embodiments include a method of forming a contact structure on a semiconductor substrate. The method including selectively depositing a metal silicide layer over a contact formed within a cavity of a substrate and a bottom surface of the cavity using a selective deposition process, including forming a residual layer on a surface of a dielectric layer forming sidewalls of the cavity, wherein a thickness of the metal silicide layer deposited over the contact is greater than a thickness of the residual layer, removing at least a portion of the residual layer formed on the dielectric layer using an etching process that comprises exposing the metal selectively deposited layer to a metal halide containing precursor, and selectively depositing a metal fill over the metal silicide layer remaining over the contact after removing the at least the portion of the residual layer using a selective metal fill process.

### CROSS-REFERENCE TO RELATED APPLICATIONS

This application is a continuation-in-part of U.S. application Ser. No. 18/400,819, filed Dec. 29, 2023, which claims the benefit of U.S. Provisional Application Ser. No. 63/532,022, filed on Aug. 10, 2023, which are both herein incorporated by reference.

### BACKGROUND

### Field

Embodiments of the present invention generally relate to methods for forming low resistivity contacts within a semiconductor device.

### Description of the Related Art

Integrated circuits have evolved into complex devices that can include billions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (e.g., DRAM (dynamic random access memory)) and logic devices, including both planar and three-dimensional structures. Three-dimensional structures include fin field-effect transistor (finFET) or metal-oxide-semiconductor field-effect transistor (MOSFET) devices.

An example of finFET or MOSFET devices includes a gate electrode on a gate dielectric layer on a surface of a semiconductor substrate. Source/drain regions are provided along opposite sides of the gate electrode. The source and drain regions are generally heavily doped regions of the semiconductor substrate. Usually a metal silicide layer, for example a titanium silicide layer, is required to form a reliable contact at the formed source and drain regions.

In a traditional middle-end-of-the-line (MEOL) contact junction formation process, a feature also referred to a cavity, a via, or a trench, is fabricated in the semiconductor substrate. MEOL contact junctions allow connections between front-end-of-the-line (FEOL) semiconductor structures and back-end-of-the-line (BEOL) interconnects. Contacts with a low resistivity are desirable in semiconductor devices. However, when MEOL contacts have high resistance, the contacts produce poor connections between the FEOL structures and the BEOL packaging interconnects, reducing the performance of the packaged semiconductor structures.

In traditional MEOL contact formation, a plasma enhanced titanium tetrachloride (TiCl₄) process is used to form a titanium silicide (TiSi) layer on a silicon or silicon germanium connection as a capping layer. Because TiSi can be easily oxidized upon air exposure, the top of the TiSi layer is then nitridated to form titanium silicon nitride (TiSiN) to protect against the oxidation of the TiSi film. The final silicide capping layer is a bilayer of TiSi and TiSiN that is formed over the field, sidewalls and contact regions formed on the substrate.

Following the TiSi/TiSiN formation, the structure is filled with a low resistivity metal such as cobalt (Co) or tungsten (W) or Molybdenum (Mo). For example, a physical vapor deposition (PVD) W process may be used to fill the structure from the bottom-up. Then, TiSi(N)/W formed on the field and the sidewall are removed by a pull-back process, and only the PVD W remains at the bottom of the structure. However, due to PVD technology limitations, it is challenging to deposit a continuous PVD W film at angled or out of the line of sight area of the capping layer which can include the surface of the formed contact and/or the junction between the formed contact and the feature's sidewall. Therefore, to ensure good W coverage especially in the sloped area, a low growth rate selective, fluorine free, atomic layer deposition (ALD) tungsten (W) process (FFW) is deposited on top of the PVD W. The ALD W layer provides not only a good F/O barrier, but also a high quality seed layer for a following high rate selective chemical vapor deposition (CVD) W process. However, such an integration flow not only has resistivity penalty due to the TiSi/TiSiN bilayer, but also high cost due to the expensive thick FFW ALD deposition process and the pull-back process for thick TiN/PVD W. The above mentioned issues discussed in relation to a W cap are also applicable to Mo capping layers, which can be formed by a PVD and CVD processes.

There is a need for improved methods to reduce contact resistance and simplified processes of contact formation.

### SUMMARY

Methods of the present disclosure provide contacts that have a reduced resistivity. Methods can integrate multiple processes on the same integrated tool as well as achieve low contact resistance (Rc). For example, a metal removal step that integrates a non-selective plasma-enhanced titanium (PE-Ti) deposition or selective chemical vapor deposition Ti (CVD-Ti) and an in-situ molybdenum (Mo) or tungsten (W) metal fill/capping eliminates a highly resistive metal silicide/nitride layer and reduces the high cost associated with the need to pull back field deposition and form a fluoride free tungsten (FFW) film at a desired thickness.

Embodiments of the disclosure include a method of forming a contact structure on a semiconductor substrate, comprising depositing a metal silicide layer over a surface of a device contact formed on a surface of a substrate, and depositing a metal capping layer over the metal silicide layer. The process of depositing the metal silicide layer includes generating a plasma in a processing region of a first processing chamber, and the plasma comprises a titanium containing precursor gas. The process of depositing the metal capping layer comprises depositing a first portion of the metal capping layer on the metal silicide layer by delivering a metal containing precursor at a first mass flow rate to the surface of the substrate that is positioned in a processing region of a second processing chamber while the substrate is maintained at a first processing temperature; and depositing a second portion of the metal capping layer on the first portion of the metal capping layer by delivering the metal containing precursor at a second mass flow rate to the surface of the substrate while the substrate is maintained at a second processing temperature, wherein the first mass flow rate is less than the second mass flow rate. The metal silicide layer can include titanium silicide (TiₓSi_{y}) or molybdenum silicide (MoSiₓ). The method can further include exposing the surface of the device contact to a preclean process gas that comprises at least one of hydrogen (H₂), ammonia (NH₃), and hydrofluoric acid (HF), wherein the exposing the surface of a device contact to a preclean process gas is performed before depositing the metal silicide layer over the surface of a device contact, and is performed by use of a non-plasma process.

Embodiments of the disclosure may further include a processing system, comprising a plurality of processing chambers, a controller, and a memory for storing instructions, which, when executed by the controller, causes the controller to perform a method of forming a contact structure on a substrate. The method of forming the of forming a contact structure on the substrate, comprising depositing a metal silicide layer over a surface of a device contact formed on a surface of the substrate and depositing a metal capping layer over the metal silicide layer. The process of depositing the metal silicide layer includes generating a plasma in a processing region of a first processing chamber, and the plasma comprises a titanium containing precursor gas. The process of depositing the metal capping layer comprises depositing a first portion of the metal capping layer on the metal silicide layer by delivering a metal containing precursor at a first mass flow rate to the surface of the substrate that is positioned in a processing region of a second processing chamber while the substrate is maintained at a first processing temperature; and depositing a second portion of the metal capping layer on the first portion of the metal capping layer by delivering the metal containing precursor at a second mass flow rate to the surface of the substrate while the substrate is maintained at a second processing temperature, wherein the first mass flow rate is less than the second mass flow rate. In some embodiments, the method further includes exposing the surface of the device contact to the preclean process gas, which is performed before depositing the metal silicide layer over the surface of a device contact and in a first processing chamber of the plurality of processing chambers. The depositing the metal silicide layer over the surface of the device contact can be performed in a second processing chamber of the plurality of processing chambers, and the depositing the metal capping layer over the metal silicide layer can be performed in a third processing chamber of the plurality of processing chambers.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIGS. 1A-1B illustrates a method for reducing contact resistance in accordance with one or more embodiments.

FIGS. 2A-2E illustrate cross-sectional views of a portion of a semiconductor structure during the method for reducing contact resistance in accordance with one or more embodiments.

FIG. 2D′ illustrates a cross-sectional view of a portion of a semiconductor structure during an alternate portion of the method in accordance with one or more embodiments.

FIG. 3 illustrates an integrated tool in accordance with one or more embodiments.

FIG. 4 depicts a schematic, cross-sectional view of a process chamber that may be used to practice the methods described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods of the present disclosure provide contacts that have a reduced resistivity. Methods can integrate multiple processes on the same integrated tool as well as achieve low contact resistance (Rc). For example, a metal removal step that integrates a conformal plasma-enhanced titanium (PE-Ti) deposition or selective chemical vapor deposition Ti (CVD-Ti) and an in-situ molybdenum (Mo) or tungsten (W) metal fill/capping eliminates a highly resistive metal silicide-nitride layer and reduces the high cost associated with the need to form a fluoride free tungsten (FFW) film at a desired thickness.

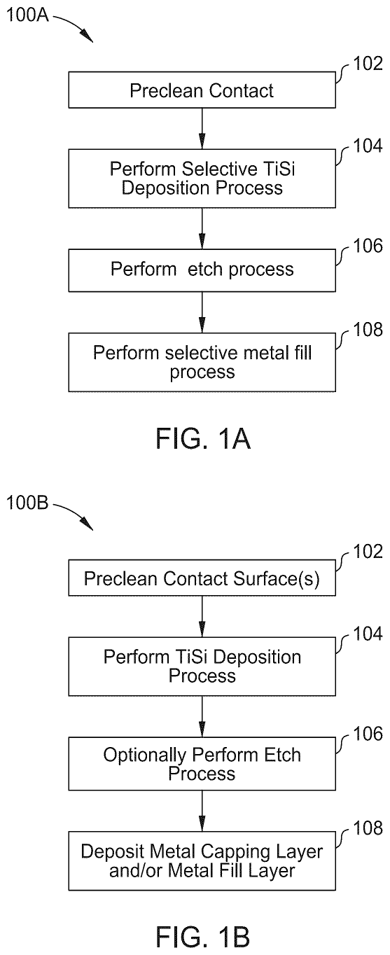

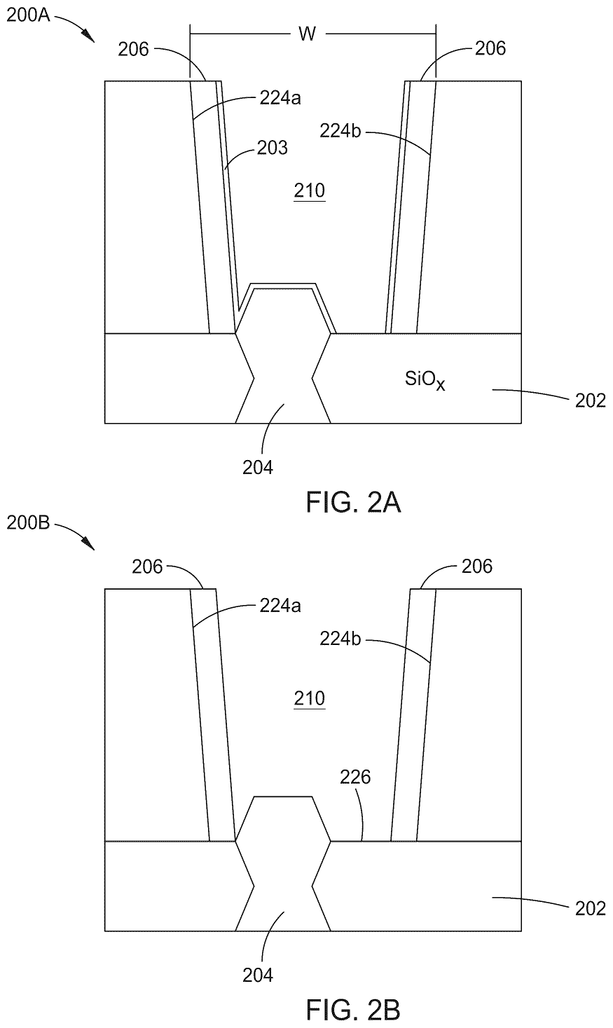

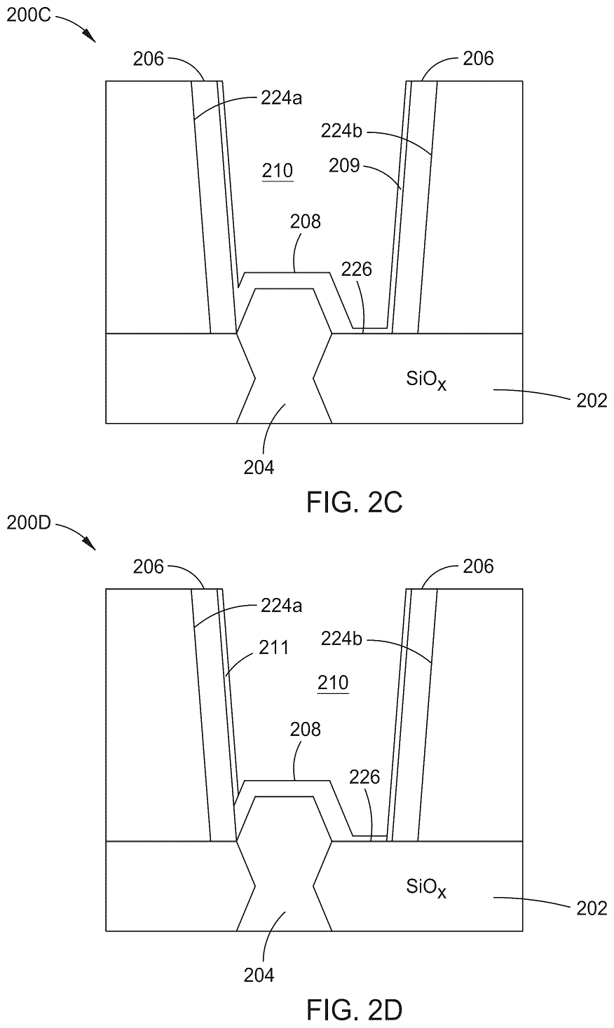

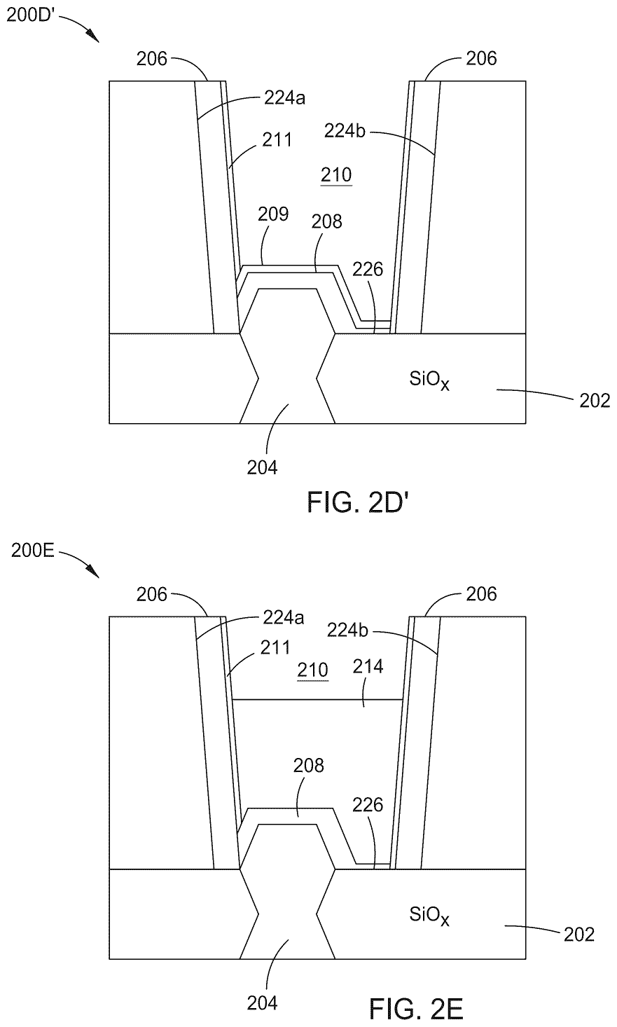

FIGS. 1A-1B illustrate a method 100 for reducing contact resistance, in accordance with one or more embodiments. FIGS. 2A-2E illustrate cross-sectional views of a portion of a semiconductor structure during the method 100 for reducing contact resistance. In the discussion of the method 100, references will be made to the views 200A-200E of FIGS. 2A-2E.

At block 102, a preclean process is performed to remove any contaminates and/or oxidation from surfaces of a contact structure as depicted in a view 200A of FIG. 2A. The contact structure has a silicon-based portion 204 (i.e., a contact) that is exposed in a cavity 210 of a substrate 202 formed of a dielectric material (e.g., silicon dioxide, silicon nitride, etc.). In some examples, the silicon-based portion 204 is formed through a bottom surface 226 of the cavity 210. In some embodiments, the silicon-based portion 204 may be a silicon material or a silicon germanium (SiGe) material. In one or more examples, a dielectric layer 206 comprising a different material than the substrate 202 may be formed on sidewalls 224a and 224b of the cavity 210. In another example, the dielectric layer is not formed on sidewalls 224a and 224b of the cavity 210 and thus the cavity 210 is formed within a dielectric layer 206 that is disposed across the surface of the substrate 202. In some embodiments, the dielectric layer 206 includes a low-k dielectric, silicon oxide, silicon nitride or other useful dielectric material. In one example, dielectric layer 206 contains a low-k dielectric material, such as a silicon carbide oxide material or a carbon doped silicon oxide material, for example, BLACK DIAMOND® II low-k dielectric material, available from Applied Materials, Inc., located in Santa Clara, California.

In one or more embodiments, cavities (e.g., vias), such as cavity 210 can have an average width W. For example, cavity 210 can have a width W (FIG. 2A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavity 210 can have an aspect ratio (depth:width) of about 1:1 to about 100:1, such as about 5:1, 10:1.

For example, as shown in the view 200B of FIG. 2B, the preclean process is performed to remove a native oxide material 203 (FIG. 2A) formed on sidewalls 224a and 224b of the cavity 210 and on the surface of the silicon-based portion 204. In one or more examples, the preclean process may include exposing the substrate 202 to the reducing agent during a thermal process or a plasma process. Reducing agents that are useful during the pre-treatment process include hydrogen (e.g., H₂ or atomic-H), ammonia (NH₃), a hydrogen and ammonia mixture (H₂/NH₃), atomic-N, hydrazine (N₂H₄), alcohols (e.g., methanol, ethanol, or propanol), derivatives thereof, plasmas thereof, or combinations thereof. Substrate 200 may be exposed to a plasma formed in-situ or remotely during the preclean process. In some embodiments of block 102, substrate 200 is exposed to a plasma preclean process to remove contaminants from the surfaces of the cavity 210. Substrate 202 may be positioned within a processing chamber, exposed to a reducing agent, and heated to a temperature within a range from about 100° C. to about 400° C., such as about 200° C. or about 250° C. In some embodiments, substrate 202 may be exposed to the plasma (e.g., in situ or remotely) for a time period within a range from about 2 seconds to about 60 seconds. The plasma may be produced at a power within the range from about 200 watts to about 1,000 watts, such as 350 watts.

In block 104, a selective deposition process is performed to produce a metal silicide layer 208 on the silicon-based portion 204 as depicted in view 200C of FIG. 2C. In one or more examples, the metal silicide layer 208 may comprise, titanium silicide (TiₓSi_{y}) which may include Ti₅Si₃, TiSi₂, TiSi, or combinations thereof. The process is selective to the silicon-based portion 204 over the dielectric material of the substrate 202, but a thin residual layer 209 may also form on the dielectric layer 206 and the bottom surface 226 of the cavity 210. The residual layer 209 may comprise Ti, TiSi, TIN, TiClₓ or the like. In one or more examples, the metal silicide layer 208 is deposited using a low selective direct plasma-enhance titanium (PE-TI) process. In other examples, the metal silicide layer 208 is deposited using a CVD TiSi process. In examples in which the dielectric layer 206 is not formed on sidewalls 224a, 224b, the residual layer 209 may be formed directly onto the sidewalls 224a and 224b.

In block 106, an etch process is performed to remove the residual layer 209 from the dielectric layer 206 formed on sidewalls 224a, 224b. In one example, the etch process is a soaking process. The soaking process may comprise soaking the substrate 202 in a processing chamber using a gas precursor. In one example the gas precursor may include molybdenum (Mo), tungsten (W), or a metal halide containing precursor used to partially or fully remove the residual layer 209 formed on sidewalls 224a, 224b. In some embodiments, the gas precursor essentially comprises a metal halide containing precursor such as tungsten pentachloride (WCl₅), tungsten hexachloride (WCl₆), or molybdenum pentachloride (MoCl₅). In some examples, the soaking process also removes a portion of the metal silicide layer 208. In one example, due to the aspect ratio of the cavity, the soaking process removes a smaller portion (i.e., less) of the metal silicide layer 208 than the residual layer 209. In another example the soaking process removes equal amounts of the metal silicide layer 208 and the residual layer 209. After the soaking process, the thickness of the metal silicide layer 208 is greater than the thickness of the residual layer 209. Thus at the competition of block 106 there is still a remaining thickness of the metal silicide layer on the bottom surface 226. In one or more examples, the soaking process may include a molybdenum halide soak using a molybdenum halide precursor such as molybdenum pentachloride (MoCl₅). In another example, the soaking process may be a tungsten halide soak using a tungsten halide precursor such as tungsten pentachloride (WCl₅) or tungsten hexachloride (WCl₆). Stated differently, the soaking process may include exposing the residual layer 209 to an amount of the gas precursor, such as a metal halide containing precursor for a period of time. The soaking process may be performed at a chamber pressure of between about 5 Torr and about 50 Torr. The soaking process may include flowing the precursor (i.e., a Mo or W precursor as described above) in the presence of a carrier gas, such as argon (or another noble gas), at flow rate between about 100 sccm and about 2,000 sccm, for example, 1,000 sccm for a period of time between 1 s and 100 s seconds, such as 10s. The soaking process may be performed at a process chamber temperature of between about 250° C. and about 500° C., for example, 400° C.

In one or more examples, as shown in the view 200D of FIG. 2D, the soaking process may partially remove the residual layer 209 formed on sidewalls 224a, 224b and/or at the very least form a passive metal residue layer 211 by passivating the remaining portion of the residual layer 209 formed on sidewalls 224a, 224b. It is believed that, due to the preferred selective deposition of the metal silicide layer 208 on the silicon-based portion 204 during block 104, the thickness of the residual layer 209 will be significantly thinner than the metal silicide layer 208 formed over the silicon-based portion 204. Therefore, during the completion of the soaking process performed during block 106 the residual layer 209 will be completely, or nearly completely (e.g., residual islands of the metal silicide layer 208), removed and only a small but equal portion of the metal silicide layer 208 formed over the silicon-based portion 204 will be removed.

In block 108, and as shown in the view 200E of FIG. 2E, a selective metal fill process may be used to deposit a metal fill 214 over the metal silicide layer 208. The metal fill 214 may comprise depositing Mo or W within the cavity 210. In one or more examples, the selective metal fill process is a bottom-up metal fill process used to selectively deposit a metal fill 214 in the cavity 210 and over the remaining metal silicide layer 208. The selective metal fill process may include exposing the metal silicide layer 208 to a metal precursor, such as a Mo precursor or a fluorine-free-tungsten (FFW) precursor along with a suitable reducing agent, such as hydrogen (H₂). In one example, Mo precursor and the FFW precursor are chlorine (CI) containing precursors. In one example, the selective metal fill process is a CVD process using a Mo precursor and is used to fill the cavity 210 and a connected junction silicide to a metal network.

In another example, the selective metal fill process can be used to form a metal fill 214 that functions as a thin metal cap to cover all junction silicide using either a Mo precursor such as MoCl₅, or a fluorine-free-tungsten (FFW) precursor. In other examples, the selective metal fill process can be an ALD deposition process or a pulsed CVD bottom-up fill process (i.e., cycling a CVD process steps and purge steps). The selective metal fill process may be performed at a chamber pressure between about 10 Torr and about 300 Torr, for example. The selective metal fill process may include flowing the metal precursor at a flow rate in the presence of a reducing agent, such as hydrogen (H₂) or diborane (B₂H₆) and a carrier gas such as argon (or another noble gas). The flow rate of the reducing agent may be between about 1,000 sccm and 20,000 sccm. The carrier gas flow rate between about 100 sccm and about 2,000 sccm, for example, 700 sccm. The selective metal fill process may be performed at a temperature of between about 250° C. and about 500° C., for example, 400° C. The etch process (block 106) and the selective metal fill process (block 108) may be performed in the same or different processing chambers.

### Selective Silicide and Metal Capping Process Sequence(s)

In some embodiments, one or more of the processes performed within the method 100 described herein can be adjusted or removed to further improve the formation of a metal capping layer over the metal silicide layer 208 formed in contact structure illustrated in FIGS. 2A-2E.

As noted above, at block 102, a preclean process is performed to remove any contaminates and/or oxidation from surfaces of a contact structure as depicted in a view 200A of FIG. 2A. The contact structure has a silicon-based portion 204 (i.e., a contact) that is exposed in a cavity 210 of a substrate 202 formed of a dielectric material (e.g., silicon dioxide, silicon nitride, etc.). In some examples, the silicon-based portion 204 is formed through a bottom surface 226 of the cavity 210. In some embodiments, the silicon-based portion 204 may be a silicon material or a silicon germanium (SiGe) material. In one or more examples, a dielectric layer 206 comprising a different material than the substrate 202 may be formed on sidewalls 224a and 224b of the cavity 210. In another example, the dielectric layer is not formed on sidewalls 224a and 224b of the cavity 210 and thus the cavity 210 is formed within a dielectric layer 206 that is disposed across the surface of the substrate 202. In some embodiments, the dielectric layer 206 includes a low-k dielectric, silicon oxide, or other useful dielectric material. In one example, dielectric layer 206 contains a low-k dielectric material, such as a silicon carbide oxide material or a carbon doped silicon oxide material, for example, BLACK DIAMOND® II low-k dielectric material, available from Applied Materials, Inc., located in Santa Clara, California.

As discussed above, the preclean process can be performed to remove a native oxide material 203 (FIG. 2A) formed on sidewalls 224a and 224b of the cavity 210 and on the surface of the silicon-based portion 204. In one or more examples, the preclean process may include exposing the substrate 202 to the preclean process gas during a thermal process or a plasma process. Preclean process gas can include hydrogen (e.g., H₂ or atomic-H), ammonia (NH₃), a hydrogen and ammonia mixture (H₂/NH₃), atomic-N, hydrazine (N₂H₄), hydrofluoric acid (HF), derivatives thereof, plasmas thereof, or combinations thereof. Substrate 200 may be exposed to a plasma formed in-situ or remotely during the preclean process. In some embodiments of block 102, the substrate is exposed to a plasma preclean process to remove contaminants from the surfaces of the cavity 210. Substrate may be positioned within a processing chamber, exposed to a preclean process gas, and heated to a temperature within a range from about 0° C. to about 200° C., such as a temperature below 120° C. In some embodiments, substrate 202 may be exposed to the plasma (e.g., in situ or remotely) for a time period within a range from about 2 seconds to about 60 seconds. The plasma may be produced at a power within the range from about 200 watts to about 1,000 watts, such as 350 watts. In some embodiments, the processes performed during block 102 include exposing the surface of the silicon-based portion 204 to a preclean process gas that comprises at least one of hydrogen (e.g., H₂ or atomic-H), ammonia (NH₃), a hydrogen and ammonia mixture (H₂/NH₃), atomic-N, hydrazine (N₂H₄), and hydrofluoric acid (HF), wherein the process can be performed by a purely thermal process (e.g., non-plasma process).

In block 104 of the metal capping method, a plasma enhanced deposition process is performed to produce a metal silicide layer 208 on the silicon-based portion 204. In one or more examples, the metal silicide layer 208 may comprise, titanium silicide (TiₓSi_{y}) which may include Ti₅Si₃, TiSi₂, TiSi, or combinations thereof. The plasma enhanced titanium deposition process allows the titanium silicide (TiₓSi_{y}) to be formed on the silicon-based portion 204 over the dielectric material of the substrate 202. It has been found that the use of the plasma enhanced titanium (PE-Ti) deposition can be used to minimize or eliminate the formation of the thin residual layer 209 on the dielectric layer 206 and the bottom surface 226 of the cavity 210. In one or more examples, the metal silicide layer 208 is deposited using a low selectivity direct plasma-enhance titanium (PE-TI) deposition process. Substrate may be positioned within a processing chamber with 350 kHz pulsing RF direct plasma, exposed to a Ti precursor along with a suitable reducing agent, such as hydrogen (H₂), and heated to a temperature within a range from about 400° C. to about 500° C., such as 440° C. In one example, the Ti precursor is a chlorine (CI) containing precursor, such as titanium tetrachloride (TiCl₄). In one example, the PE-Ti deposition process is a PECVD process using a Ti precursor and is used to form a TiSi containing layer that is between about 30 and 80 angstroms (Å) thick. In some embodiments, the substrate may be exposed to the plasma (e.g., direct or remotely) for a time period within a range from about 50 seconds to about 200 seconds. The plasma may be produced at a power within the range from about 75 watts to about 1,000 watts, such as 350 watts. In some embodiments of the processing region of the processing PE-Ti processing chamber is maintained at a pressure between 0.5 Torr and 300 Torr.

In some embodiments of block 104, a metal silicide layer 208 that comprises molybdenum silicide (MoSiₓ) is formed on the silicon-based portion 204. In one or more examples, the metal silicide layer 208 is deposited using a low selectivity direct plasma-enhance deposition process, which is similar to the processes described above. In one or more other examples, the metal silicide layer 208 is deposited by use of a non-plasma process that includes use of a Mo containing precursor, such as molybdenum pentachloride (MoCl₅). In some embodiments, the substrate may be positioned within a processing chamber and exposed to the Mo containing precursor along with a suitable reducing agent, such as hydrogen (H₂) and heated to a temperature within a range from about 300° C. to about 500° C., while the processing region of the processing chamber is maintained at a pressure between 0.5 Torr and 300 Torr. In this example, the process performed during block 104 is used to form a MoSiₓ containing layer that is between about 30 and 80 angstroms (Å) thick.

In some embodiments of method 100, block 106 (FIG. 1B) is optionally performed after block 104 has been performed. It has been found that the processes performed during block 106 can be helpful to allow the selective formation of a tungsten (W) layer on the formed silicide layer by use of a fluorine-free tungsten (FFW) deposition process in a subsequent processing operation. However, the exposure of the structure to the soaking process precursor during block 106 can in some processing sequences undesirably etch the deposited silicide layer and exposed dielectric layer(s). Therefore, in one or more embodiments of method 100, block 106 is not performed during method 100 to avoid and/or minimize the possibility of the soaking process precursor etching the deposited silicide layer and exposed dielectric layers. In one processing example, block 106 is not performed during the completion of a method 100 that includes the formation of a molybdenum (Mo) containing capping layer over the formed silicide layer in a subsequent processing step.

In block 108 of the method 100, as illustrated in FIG. 1B, a metal capping layer process may be used to deposit a metal capping layer 209 (FIG. 2D′) over the metal silicide layer 208. The metal capping layer may include depositing a layer of Mo or W on the formed silicide layer and within the cavity 210. In one or more examples, the metal capping process is used to selectively deposit a metal capping layer in the cavity 210 and over the remaining metal silicide layer 208. The metal capping process can be used to form a thin layer (e.g., 30 Å-200 Å) that covers the exposed surface of the formed metal silicide layer 208. The metal capping layer process may include exposing the metal silicide layer 208 to a metal precursor, such as a Mo precursor along with a suitable reducing agent, such as hydrogen (H₂). In one example, the Mo precursor is a chlorine (Cl) containing precursor, such as molybdenum pentachloride (MoCl₅). In one example, the metal capping layer deposition process is a CVD process using a Mo precursor and is used to form a Mo containing layer that is between about 30 and 200 angstroms (Å) thick.

In some embodiments, the metal capping layer formation process includes a multiple step deposition sequence that includes the delivery of a metal containing precursor and a reducing agent to a surface of a substrate and adjusting one or more of the deposition processing parameters (e.g., temperature, mass flow rate, and/or processing pressure) between different steps within the multiple step deposition sequence. In one example, the selective metal capping layer formation process includes at least a two-step capping layer deposition process in which the first step includes the delivery of a first precursor at a first mass flow rate and controlling the temperature of the substrate to a first processing temperature, and a second step that includes the delivery of the first precursor at a second mass flow rate and controlling the temperature of the substrate to a second processing temperature. In some embodiments, the first mass flow rate is less than the second mass flow such that the concentration of the first precursor within a processing region of a processing chamber during the first step is less than the concentration of the first precursor within a processing region of a processing chamber during the second step. As discussed above, in some embodiments, the multiple step deposition sequence performed during block 108 is performed after block 104 has been completed, and without performing block 106. Therefore, in some embodiments, the first step of a multiple step metal capping layer deposition sequence may include process parameters (e.g., metal precursor flow rate to reducing agent flow rate ratio) that are used to partially remove the residual layer 209 formed on sidewalls 224a, 224b and/or at the very least form a passive metal residue layer 211 by passivating the remaining portion of the residual layer 209 formed on sidewalls 224a, 224b. In one example, during processing the metal precursor flow rate to reducing agent flow rate ratio is set to a level where the reducing agent flow rate is less than required (i.e., deficient) to cause a complete reaction of all of or a significant part of the metal precursor flowing over a surface of the substrate.

In one embodiment of block 108, the multiple step metal capping layer formation process includes a first deposition process step that includes the delivery of a Mo containing precursor (e.g., MoCl₅) at a first mass flow and a reducing agent (e.g., H₂) at a second mass flow rate to a surface of a substrate that is maintained at a processing temperature of less than 400° C., such as between about 300° C. and about 400° C., or between about 350° C. and about 375° C. Then performing a second deposition process step that includes the delivery of the Mo containing precursor (e.g., MoCl₅) at a third mass flow and a reducing agent (e.g., H₂) at a fourth mass flow rate to the surface of the substrate that is maintained at a processing temperature greater than 400° C., such as between about 400° C. and about 500° C. The first mass flow rate being less than the third mass flow rate, and also first mass flow rate being maintained at a flow rate that will not create a precursor concentration that will significantly etch the exposed surfaces of the silicide layer and dielectric layers. The metal capping layer formation process may be performed at a chamber pressure between about 10 Torr and about 300 Torr, for example. In some embodiments, the first and second deposition process steps are performed in the same processing chamber disposed within a processing system. In some embodiments, the first and second deposition process steps are performed in different processing chambers disposed within a processing system.

In one embodiment of block 108, the multiple step metal capping layer formation process includes the use of a precursor delivery system that includes two or more fluid delivery lines that are each configured to deliver a fluid, such as the metal containing precursor, carrier gas, reducing agent containing gas, and/or inert gas at different flow rates, temperatures and/or pressures. As will be discussed in further detail below, a process chamber 400 can include a precursor delivery system, such as a gas source 450, that is configured to deliver the metal containing precursor, carrier gas, reducing agent containing gas, and inert gas at different flow rates, temperatures and/or pressures to the surface of a substrate. The gas source 450 can include a first metal containing precursor source 451, a second metal containing precursor source 452, a reducing agent containing gas source 453 and a carrier gas source 454. In some embodiments, components within the first metal containing precursor source 451 and the second metal containing precursor source 452 are heated (e.g., heated ampoules and/or heated fluid deliver lines) during processing so that the fluid properties and flow rates of the precursor provided from the metal containing precursor sources can be controlled. In one example, the first metal containing precursor source 451 and the second metal containing precursor source 452 each include an ampoule that contains the same metal containing precursor (e.g., MoCl₅) that is heated to different fluid delivery temperatures. In one example, the first metal containing precursor source 451 includes an ampoule that is heated to a first ampoule temperature and is configured to deliver a metal containing precursor to the process chamber and surface of the substrate during the first deposition process step of the multiple step metal capping layer formation process, and the second metal containing precursor source 452 includes an ampoule that is heated to a second ampoule temperature and is configured to deliver the metal containing precursor to the process chamber and surface of the substrate during the second deposition process step of the multiple step metal capping layer formation process. In one example, an ampoule within the first metal containing precursor source 451 that contains a metal halide containing precursor (e.g., MoCl₅) is heated to a first ampoule temperature that is between 55° C. and 67° C. and an ampoule within the second metal containing precursor source 452 that also contains the same metal halide containing precursor (e.g., MoCl₅) is heated to a second ampoule temperature that is greater than the first ampoule temperature, such as between 67° C. and 95° C. during processing. The gas source 450 can also be configured to deliver a carrier gas with the metal containing precursor at different flow rates during each of the multiple step metal capping layer formation process steps. The gas source 450 can be configured to also provide a dilution gas (e.g., Ar) from the carrier gas source 453 at different flow rates during each of the multiple step metal capping layer formation process steps.

In some embodiments of block 108, the deposition process includes the use of a capacitively coupled plasma (CCP) plasma process performed in a plasma processing chamber that includes a showerhead that is configured to provide one or more process gases to a processing region of a plasma processing chamber. In some embodiments, the metal capping layer deposition process can include a plasma deposition process in which a precursor gas, such as a molybdenum (Mo) containing precursor gas, is added to a flow of a treatment gas composition to form a deposition gas. In some embodiments, the treatment gas will include the reducing agent containing gas (e.g., H₂) and an inert gas such as argon (Ar). The formed deposition gas is used to cause the formation of the metal capping layer, such as a molybdenum containing layer. In some embodiments, the molybdenum containing precursor gas can include molybdenum pentachloride (MoCl₅). The metal capping layer formation process may be performed in the processing region of a plasma processing chamber for a time period between 0.5 and 10 seconds, such as about 3 seconds at a pressure between 2 and 50 Torr. In some embodiments of the multiple step metal capping layer formation process the substrate is maintained at a temperature between 300° C. and 500° C., while the processing region of the processing chamber is maintained at a pressure between 10 Torr and 300 Torr. During processing a hydrogen containing reducing agent gas, such as H₂ can be provided at a flow rate of 2,000 sccm to 22,500 sccm, while a carrier gas flow rate of 100 sccm to 2,000 sccm is provided to an ampoule that is maintained at a temperature 55° C. to 95° C. The metal capping layer deposition process can be performed at a first RF power level at a first RF frequency between about 1 megahertz (MHz) and 120 MHz (e.g., 13.56 MHz), such as between 50 W and 500 W, such as between 50 W and 150 W. The processing gas is provided at the processing gas flow rate and the reactive gas is provided at the first reactive gas flow rate during the deposition time period. Thus, a ratio between the first reactive gas flow rate and the processing gas flow rate ranges from 1:200 and 5:1 during the deposition time period. In other examples, the metal capping layer formation process can be an ALD deposition process or a pulsed CVD process (i.e., cycling a CVD process steps and purge steps).

In block 108, in some embodiments, after performing the metal capping layer formation process, a selective metal fill process (FIG. 2E) may be used to deposit the metal fill 214 over the formed metal capping layer (FIG. 2D′). As discussed above, the metal fill 214 may comprise depositing Mo or W within the cavity 210. In one or more examples, the selective metal fill process is a bottom-up metal fill process used to selectively deposit the metal fill 214 in the cavity 210 and over the formed metal capping layer. As discussed above, the selective metal fill process may include exposing the metal capping layer to a metal precursor, such as a Mo precursor along with a suitable reducing agent, such as hydrogen (H₂). The selective metal fill process may include the process steps described above in relation to forming the selective metal fill layer on the silicide layer.

### Processing System Examples

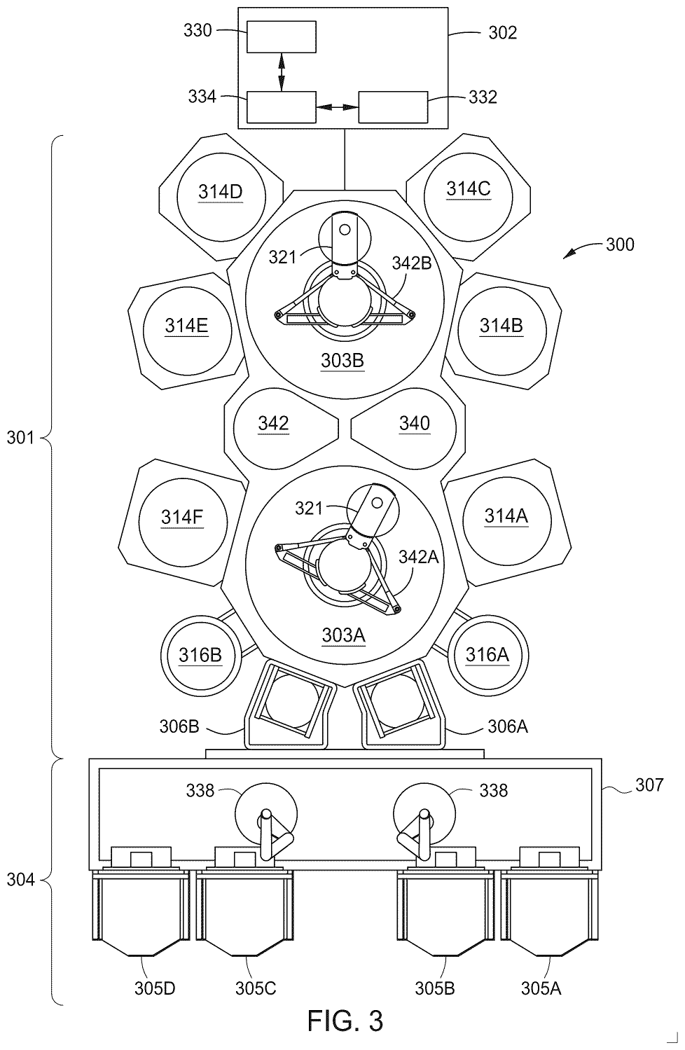

The methods of the present disclosure may be performed in individual process chambers that may be provided as part of a cluster tool, for example, the integrated tool 300 (e.g., cluster tool) described below with respect to FIG. 3. The advantage of using an integrated tool 300 is that there is no vacuum break between chambers and, therefore, no requirement to degas and pre-clean a substrate before treatment in a chamber. For example, in some embodiments the methods of the present disclosure may advantageously be performed in an integrated tool such that there are limited or no vacuum breaks between processes, limiting or preventing contamination of the substrate such as oxidation and the like. The integrated tool 300 includes a vacuum-tight processing platform 301, a factory interface 304, and a system controller 302. The processing platform 301 comprises multiple processing chambers, such as 314A, 313B, 314C, 314D, 314E, and 314F operatively coupled to a vacuum substrate transfer chamber (transfer chambers 303A, 303B). The factory interface 304 is operatively coupled to the transfer chamber 303A by one or more load lock chambers (two load lock chambers, such as 306A and 306B)

In some embodiments, the factory interface 304 comprises at least one docking station 307, at least one factory interface robot 338 to facilitate the transfer of the semiconductor substrates. The docking station 307 is configured to accept one or more front opening unified pod (FOUP). Four FOUPS, such as 305A, 305B, 305C, and 305D are shown in the embodiment of FIG. 3. The factory interface robot 338 is configured to transfer the substrates from the factory interface 304 to the processing platform 301 through the load lock chambers, such as 306A and 306B. Each of the load lock chambers 306A and 306B have a first port coupled to the factory interface 304 and a second port coupled to the transfer chamber 303A. The load lock chamber 306A and 306B are coupled to a pressure control system (not shown) which pumps down and vents the load lock chambers 306A and 306B to facilitate passing the substrates between the vacuum environment of the transfer chamber 303A and the substantially ambient (e.g., atmospheric) environment of the factory interface 304. The transfer chambers 303A, 303B have vacuum robots 342A, 342B disposed in the respective transfer chambers 303A, 303B. The vacuum robot 342A is capable of transferring substrates 321 between the load lock chamber 306A, 306B, the processing chambers 314A and 314F and a cooldown station 340 or a pre-clean station 342. The vacuum robot 342B is capable of transferring substrates 321 between the cooldown station 340 or pre-clean station 342 and the processing chambers 314B, 314C, 314D, and 314E.

In some embodiments, the processing chambers 314A, 314B, 314C, 314D, 314E, and 314F are coupled to the transfer chambers 303A, 303B. The processing chambers 314A, 314B, 314C, 314D, 314E, and 314F may comprise, for example, preclean chambers, ALD process chambers, PVD process chambers, remote plasma chambers, CVD chambers, or the like. The chambers may include any chambers suitable to perform all or portions of the methods of the present disclosure, as discussed above. In some embodiments, one or more optional service chambers (shown as 316A and 316B) may be coupled to the transfer chamber 303A. The service chambers 316A and 316B may be configured to perform other substrate processes, such as degassing, orientation, substrate metrology, cool down, and the like.

The processing chambers 314A, 314B, 314C, 314D, 314E, and 314F may be any appropriate chamber for processing a substrate. In some examples, a processing chamber may be capable of performing an etch process, a cleaning process, an annealing process, a CVD deposition process, or an ALD deposition processes. As used herein, CVD refers to chemical vapor deposition and ALD refers to atomic line deposition. In some embodiments, a processing chamber is a Selectra™ Etch chamber available from Applied Materials of Santa Clara, Calif. In some embodiments, a processing chamber is a SiCoNi™ Pre-clean chamber available from Applied Materials of Santa Clara, Calif. In some embodiments, a processing chamber may be a Centura™ Epi chamber, Volta™ CVD/ALD chamber, or Encore™ PVD chamber, all available from Applied Materials of Santa Clara, Calif.

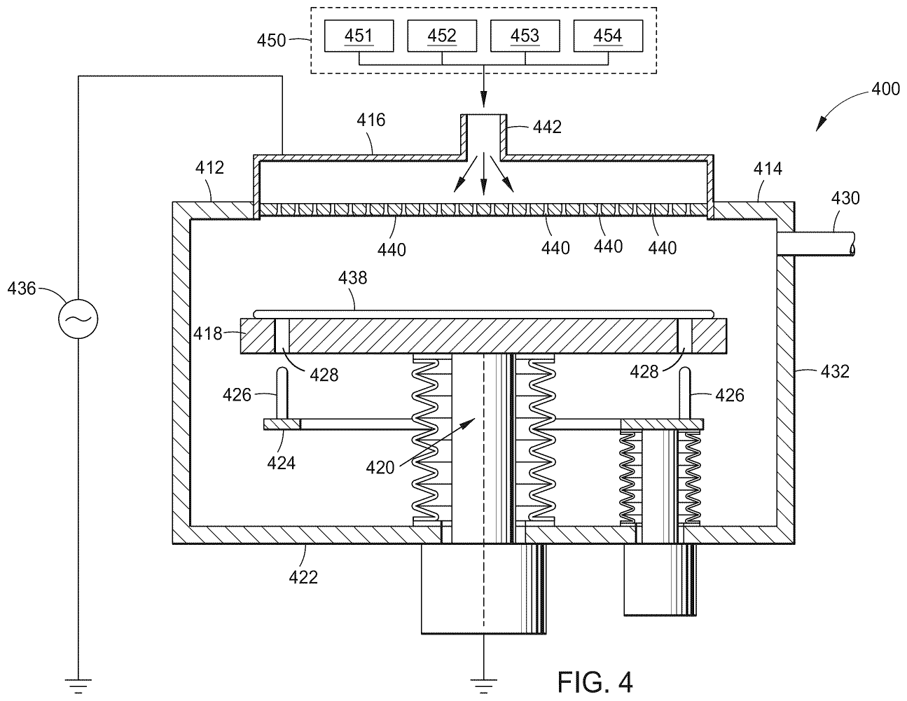

FIG. 4 illustrates a schematic sectional view of a process chamber 400 in which the methods of the present invention may be carried out. Process chamber 400 can be positioned within one or more of the processing chambers 314A, 314B, 314C, 314D, 314E, and 314F described above. Process chamber 400 includes a deposition chamber 412 that has a top wall 414 with an opening therethrough and a first electrode 416, such as a showerhead, within the opening. Within chamber 412 is a susceptor 418 in the form of a plate that extends parallel to the first electrode 416. The susceptor 418 is connected to ground, or alternately biased by use of RF or DC source (not shown), so that it serves as a second electrode. The susceptor 418 is mounted on the end of a shaft 420 that extends vertically through a bottom wall 422 of the deposition chamber 412. The shaft 420 is movable vertically so as to permit movement of the susceptor 418 vertically toward and away from the first electrode 416. A lift plate 424 extends horizontally between the susceptor 418 and the bottom wall 422 of the deposition chamber 412 substantially parallel to the susceptor 418. Lift pins 26 project vertically upwardly from the lift plate 424. The lift-off pins 426 are positioned to be able to extend through holes 428 in the susceptor 418, and are of a length slightly longer than the thickness of the susceptor 418. While there are only two lift pins 426 shown, there may be more of the lift-off pins 426 spaced around the lift-off plate 424. A gas outlet 430 extends through a side wall 432 of the deposition chamber 412 and is connected to a pump for evacuating the deposition chamber 412. A gas inlet pipe 442 extends through the first electrode 416 of the deposition chamber 412, and is connected to a gas source 450 to provide one or more gases through the first electrode 416 and to a substrate 438 disposed on the susceptor 418. The first electrode 416 includes a plate 440 with holes 444 that are configured to deliver the one or more gases to the substrate 438. In some embodiments, the first electrode 416 is connected to an RF power source 436.

As discussed above, the gas source 450 is a precursor delivery system that includes two or more fluid delivery lines that are each configured to deliver a fluid, such as the metal containing precursor, carrier gas, reducing agent containing gas, and/or inert gas at different flow rates, temperatures and/or pressures to the inlet pipe 442, first electrode 416, and substrate 438. The gas source 450 can include a first metal containing precursor source 451, a second metal containing precursor source 452, a reducing agent containing gas source 453 and a carrier gas source 454. In some embodiments, the first metal containing precursor source 451 and the second metal containing precursor source 452 include heating elements that each configured to heat and control the temperature of one or more components (e.g., ampoules and/or fluid deliver lines) within the sources during processing. In one example, as discussed above, the first metal containing precursor source 451 and the second metal containing precursor source 452 each include an ampoule that contains the same metal containing precursor (e.g., MoCl₅) that are heated to different fluid delivery temperatures.

In some embodiments, the two or more of blocks 102, 104, 106, and 108 of method 100 are performed in different processing chambers with the integrated tool 300. In some embodiments, one or more of the processing chambers 314A, 314B, 314C, 314D, 314E, and 314F used to perform one or more of the processes described in relation to blocks 102, 104, 106, and 108 are plasma processing chambers, such as a preclean chamber and/or a plasma enhanced CVD chamber (e.g., capacitively coupled plasma chamber). In one example, the processing chamber 314A is configured to perform the processes described in block 102, the processing chamber 314B is configured to perform the processes described in block 104, the processing chamber 314C is configured to perform the processes described in block 106, and the processing chamber 314D is configured to perform one or more of the deposition processes described in relation to block 108. In another example, the processing chamber 314A is configured to perform the processes described in block 102, the processing chamber 314B is configured to perform the processes described in block 104, the processing chamber 314C is configured to perform the processes described in block 106 and also perform one or more of the deposition processes described in relation to block 108.

In some embodiments, blocks 102, 104, and 108 of method 100 used to form a metal capping layer on a surface of a contact are performed in different processing chambers within the integrated tool 300. In some embodiments, the processes performed in blocks 102, 104, and 108 of method 100 are sequentially performed within the processing chambers within the integrated tool 300 without exposing the substrate to air, or in other words breaking vacuum. In some embodiments, one or more of the processing chambers 314A, 314B, 314C, 314D, 314E, and 314F used to perform one or more of the processes described in relation to blocks 102, 104, and 108 are plasma processing chambers, such as a preclean chamber and/or a plasma enhanced CVD chamber (e.g., capacitively coupled plasma chamber). In one example, the processing chamber 314A is configured to perform the processes described in block 102, the processing chamber 314B is configured to perform the processes described in block 104, and the processing chamber 314C is configured to perform one or more of the deposition processes described in relation to block 108. In another example, the processing chamber 314A is configured to perform the processes described in block 102, the processing chamber 314B is configured to perform the processes described in block 104, the processing chamber 314C is configured to perform the first deposition process step of a multiple step metal capping layer formation process described in block 108, and the processing chamber 314D is configured to perform the second deposition process step of the multiple step metal capping layer formation process described in block 108. In yet another example, the processing chamber 314A is configured to perform the processes described in block 102, the processing chamber 314B is configured to perform the processes described in block 104, the processing chamber 314C is configured to perform the first and the second deposition process steps of the multiple step metal capping layer formation process described in block 108. In yet another example, the processing chamber 314A is configured to perform the processes described in block 102, the processing chamber 314B is configured to perform the processes described in block 104, the processing chamber 314C is configured to perform the first deposition process step of a multiple step metal capping layer formation process described in block 108, the processing chamber 314D is configured to perform the second deposition process step of the multiple step metal capping layer formation process described in block 108, and the processing chamber 314E is configured to perform the selective metal fill process step described in block 108. In yet another example, the processing chamber 314A is configured to perform the processes described in block 102, the processing chamber 314B is configured to perform the processes described in block 104, the processing chamber 314C is configured to perform the first deposition process step of a multiple step metal capping layer formation process described in block 108, the processing chamber 314D is configured to perform the second deposition process step of the multiple step metal capping layer formation process and also configured to perform the selective metal fill process step that are both described in relation to block 108.

The system controller 302 controls the operation of the tool 300 using a direct control of the process chambers 314A, 314B, 314C, 314D, 314E, and 314F or alternatively, by controlling the computers (or controllers) associated with the process chambers 314A, 314B, 314C, 314D, 314E, and 314F and the tool 300. In operation, the system controller 302 enables data collection and feedback from the respective chambers and systems to optimize performance of the tool 300. The system controller 302 generally includes a Central Processing Unit (CPU) 330, a memory 334, and a support circuit 332. The CPU 330 may be any form of a general-purpose computer processor that can be used in an industrial setting. The support circuit 332 is conventionally coupled to the CPU 330 and may comprise a cache, clock circuits, input/output subsystems, power supplies, and the like. Software routines, such as a method as described above may be stored in the memory 334 and, when executed by the CPU 330, transform the CPU 330 into a specific purpose computer (system controller) 302. The software routines may also be stored and/or executed by a second controller (not shown) that is located remotely from the tool 300.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below. All numerical values are “about” or “approximately” the indicated value, and taken into account experimental error and variations that would be expected by a person having ordinary skill in the art.

Likewise whenever a composition, an element or a group of elements is preceded with the transitional phrase “comprising”, it is understood that we also contemplate the same composition or group of elements may be modified with other transitional phrases, such as “consisting essentially of,” “consisting of”, “selected from the group of consisting of,” or “is” preceding the recitation of the composition, element, or elements and vice versa. The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the claimed features, additionally, the phrases do not exclude impurities and variances normally associated with the elements and materials used.

While the foregoing is directed to embodiments of the present principles, other and further embodiments of the principles may be devised without departing from the basic scope thereof.

What is claimed is:

1. A method of forming a contact structure on a semiconductor substrate, comprising:
depositing a metal silicide layer over a surface of a device contact formed on a surface of a substrate, wherein depositing the metal silicide layer comprises:
generating a plasma in a processing region of a first processing chamber, and
the plasma comprises a titanium containing precursor gas; and
depositing a metal capping layer over the metal silicide layer, wherein depositing the metal capping layer comprises:
depositing a first portion of the metal capping layer on the metal silicide layer by delivering a metal containing precursor at a first mass flow rate to the surface of the substrate that is positioned in a processing region of a second processing chamber while the substrate is maintained at a first processing temperature; and
depositing a second portion of the metal capping layer on the first portion of the metal capping layer by delivering the metal containing precursor at a second mass flow rate to the surface of the substrate while the substrate is maintained at a second processing temperature,
wherein the first mass flow rate is less than the second mass flow rate.

2. The method of claim 1, wherein
depositing the first portion of the metal capping layer further comprises simultaneously delivering a gas comprising a reducing agent that comprises hydrogen (H₂) and the metal containing precursor to the surface of the substrate, and
the metal containing precursor comprises molybdenum and a halogen.

3. The method of claim 2, wherein the metal silicide layer comprises titanium silicide (TiₓSi_{y}) or molybdenum silicide (MoSiₓ).

4. The method of claim 1, further comprising:
exposing the surface of the device contact to a preclean process gas that comprises at least one of hydrogen (H₂), ammonia (NH₃), and hydrofluoric acid (HF), wherein the exposing the surface of a device contact to a preclean process gas is performed before depositing the metal silicide layer over the surface of a device contact, and is performed by use of a non-plasma process.

5. The method of claim 1, further comprising selectively depositing a metal fill layer over the metal capping layer, wherein selectively depositing the metal fill layer comprises exposing the metal capping layer to a metal halide containing precursor and a reducing agent.

6. The method of claim 5, wherein the selectively deposited metal fill layer comprises molybdenum (Mo).

7. The method of claim 6, wherein the selective metal fill process is an atomic layer deposition (ALD) process, a pulsed chemical vapor deposition (CVD) process, or a CVD process.

8. The method of claim 1, wherein
depositing the first portion of the metal capping layer on the metal silicide layer, wherein depositing the first portion comprises:
generating a plasma in the processing region of the second processing chamber, and
the plasma formed while depositing the first portion of the metal capping layer comprises the metal containing precursor which comprises a molybdenum containing precursor gas that has a first concentration in the processing region of the second processing chamber; and
depositing the second portion of the metal capping layer on the first portion of the metal capping layer, wherein depositing the second portion comprises:
generating a plasma in the processing region of the second processing chamber, and
the plasma formed while depositing the second portion of the metal capping layer comprises the metal containing precursor which comprises the molybdenum containing precursor gas that has a second concentration in the processing region of the second processing chamber.

9. The method of claim 8, wherein first concentration is less than the second concentration.

10. The method of claim 1, further comprising exposing the surface of a device contact to a preclean process gas that comprises hydrofluoric acid (HF), wherein
exposing the surface of a device contact to a preclean process gas is performed before depositing the metal silicide layer over the surface of a device contact, and
the exposing the surface of the device contact to the preclean process gas, the depositing the metal silicide layer over the surface of a device contact, and the depositing the metal capping layer over the metal silicide layer are sequentially performed without exposing the substrate to air.

11. The method of claim 1, wherein depositing the second portion of the metal capping layer on the first portion of the metal capping layer comprises:
delivering the metal containing precursor at the second mass flow rate to the surface of the substrate while the substrate is maintained at the second processing temperature while being disposed within a third processing chamber.

12. A processing system, comprising:
a plurality of processing chambers;
a controller;
a memory for storing instructions, which, when executed by the controller, causes the controller to perform a method of forming a contact structure on a substrate, the method comprising:
depositing a metal silicide layer over a surface of a device contact formed on a surface of the substrate, wherein depositing the metal silicide layer comprises
generating a plasma in a processing region of a first processing chamber, and
the plasma comprises a titanium containing precursor gas; and
depositing a metal capping layer over the metal silicide layer, wherein depositing the metal capping layer comprises:
depositing a first portion of the metal capping layer on the metal silicide layer by delivering a metal containing precursor at a first mass flow rate to the surface of the substrate that is positioned in a processing region of a second processing chamber while the substrate is maintained at a first processing temperature; and
depositing a second portion of the metal capping layer on the first portion of the metal capping layer by delivering the metal containing precursor at a second mass flow rate to the surface of the substrate while the substrate is maintained at a second processing temperature,
wherein the first mass flow rate is less than the second mass flow rate.

13. The processing system of claim 12, wherein the metal containing precursor essentially comprises molybdenum pentachloride (MoCl₅).

14. The processing system of claim 12, wherein the metal silicide layer comprises titanium silicide (TiₓSi_{y}) or molybdenum silicide (MoSiₓ).

15. The processing system of claim 12, wherein the method further comprises:
exposing the surface of the device contact to a preclean process gas that comprises at least one of hydrogen (H₂), ammonia (NH₃), and hydrofluoric acid (HF), wherein the exposing the surface of a device contact to a preclean process gas is performed before depositing the metal silicide layer over the surface of a device contact, and is performed by use of non-plasma process.

16. The processing system of claim 12, further comprising selectively depositing a metal fill layer over the metal capping layer, wherein selectively depositing the metal fill layer comprises exposing the metal capping layer to a metal halide containing precursor and a reducing agent.

17. The processing system of claim 16, wherein the metal fill layer comprises molybdenum (Mo).

18. The processing system of claim 12, wherein the method further comprises exposing the surface of a device contact to a preclean process gas that comprises hydrofluoric acid (HF) in a first processing chamber of the plurality of processing chambers, wherein
the exposing the surface of a device contact to the preclean process gas is performed before depositing the metal silicide layer over the surface of a device contact,
the depositing the metal silicide layer over the surface of the device contact is performed in a second processing chamber of the plurality of processing chambers, and
the depositing the metal capping layer over the metal silicide layer in a third processing chamber of the plurality of processing chambers.
